(19) United States
(12) Patent Application Publication
(10) Pub. No.: US 2003/0205124 A1
(43) Pub. Date: Nov. 6, 2003

(54) Method and system for retrieving and sequencing music by rhythmic similarity

(76) Inventors: Jonathan T. Foote, Menlo Park, CA (US); Matthew L. Cooper, San Francisco, CA (US)

Correspondence Address: Martin C. Fliesler, FLIESLER DUBB MEYER & LOVEJOY LLP, Four Embarcadero Center, Fourth Floor, San Francisco, CA, 94111-4156, US

(21) Appl. No.: 10/405,192

(22) Filed: Apr. 1, 2003

Related U.S. Application Data
(60) Provisional application No. 60/376,766, filed on May 1, 2002.

(51) Int. Cl. G11C 5/00

(52) U.S. Cl. 84/608

(57) ABSTRACT

A method for measuring the similarity between the beat spectra of two or more audio works. A distance formula is used to measure the similarity by rhythm and tempo between shortened beat spectra B₁(L) and B₂(L). The result is a vector which measures the similarity of rhythm and tempo. A distance formula is used to measure the rhythmic similarity between the scaled beat spectra B₁(L) and B₂(L). The result is a measure of rhythmically similar music regardless of the tempo. The method can be used in a wide variety of applications, including concatenating music with similar tempos, automatic music sequencing, classification of music into genres, search for music with similar rhythmic structures, search for music with similar rhythmic and tempo structures, and ranking music according to a similarity measure.

### CLAIM OF PRIORITY

This application claims priority to U.S. Provisional Application No. 60/376,766 filed May 1, 2002, entitled “Method For Retrieving And Sequencing Music by Rhythmic Similarity,” incorporated herein by reference.

### RELATED APPLICATION

This application incorporates by reference U.S. patent application Ser. No. 09/569,230, entitled “A Method for Automatic Analysis of Audio Including Music and Speech,” filed on May 11, 2000 and the article “Visualizing Music and Audio Using Self-Similarity,” Proc. ACM Multimedia 99, Orlando, Fla. authored by Jonathan T. Foote, et al.

### BACKGROUND

1. Field of the Invention

The present disclosure relates to methods for comparing representations of music by rhythmic similarity and more particularly, to the application of various methods to measure rhythmic and tempo similarity between auditory works.

2. Description of Related Art

Several approaches exist for performing audio rhythm analysis. One approach details how energy peaks across frequency sub-bands may be detected and correlated. The incoming waveform is decomposed into frequency bands, and the amplitude envelope of each band is extracted. The amplitude envelope is a time-varying representation of the amplitude or loudness of the sample at particular points in the sound file. The amplitude envelopes are differentiated and the half-wave rectified. This approach picks correlated peaks from all band frequencies, with a subsequent phase estimation, in an attempt to match human beat perception. However, this approach usually only performs ideally in music with a strong percussive element or a short-term periodic wideband source such as drums.

Another approach for performing audio similarity analysis depends on restrictive assumptions such as the music must be in 4/4 time and have a bass drumbeat on the downbeat. Such an approach measures one dominant tempo by various known methods including averaging the amplitudes of the peaks in the beat spectra over many beats, rejecting out-of-band results, or Kalman filtering. Such approaches are further limited to tempo analysis and do not measure rhythm similarity.

Another approach of performing similarity analysis computes rhythmic similarity for a system for searching a library of rhythm loops. Here, a “bass loudness time-series” is generated by weighting the short-time Fourier transform (“STFT”) of the audio waveform. A peak in the power spectrum of this time series is chosen as the fundamental period. The Fourier result is normalized and quantized into durations of ⅙ of a beat, so that both duplet and triplet sub-divisions can be represented. This serves as a feature vector for tempo invariant rhythmic similarity comparison. This approach works for drum-only tracks, but is typically less robust on music with significant low frequency energy.

Another approach for performing audio similarity computes a rhythmic self-similarity measure depicted as a “beat histogram.” Here, an autocorrelation is performed on the amplitudes of wavelet-like features, across multiple windows so that many results are available. Major peaks in each auto correlation are detected and accumulated in the histogram. The lag time of each peak is inverted to attain a tempo axis for the histogram which is measured in beats per minute. The resulting beat histogram is a measure of periodicity versus tempo.

A limitation and deficiency of the aforementioned design is its heavy reliance on peak-picking in a number of auto correlations in order to determine the rhythmic self-similarity measurement. For genre classification, features are derived from the beat histogram including the tempo of the major peaks and amplitude rations between them. By relying on peak-picking to produce the beat histogram, these methods result in a count of discrete measurements of self-similarity rather than one continuous representation. Thus, the beat histogram is a less precise measure of audio self-similarity.

Researchers have also developed applications which perform simple tempo analysis. Applications proposed may serve as an “Automatic DJ” and may cover both track selection by rhythmic similarity and cross-fading. Successful cross-fading occurs where the transition from one musical work to the next musical work is near seamless. Near seamless transitions maybe achieved where the tempo and rhythm of the succeeding musical work closely parallels the tempo and rhythm of the current musical work. The system for track selection is based on a tempo “trajectory,” or a function of tempo versus time. The tempo trajectory is quantized into time “slots” based on the number of works available. Both slots and works are ranked by tempo and the works are assigned to the slots according to the ranking. For example, the second highest slot gets the track with the second fastest tempo. However, this system is designed for a narrow genre of music, such as dance music, where the tempos of the musical work are relatively simple to detect. A tempo may be simple to detect because of its repetitive and percussive nature. Moreover, this type of music typically contains constant tempos across a work, making the tempo detection process more simplistic. Thus, this system is not robust across many types of music.

Therefore, what is needed is a robust method of performing audio similarity analyses which works for any type of music or audio work in any genre and does not depend on particular attributes. The robust similarity method should compare the entire beat spectra, or another measurement of acoustic self-similarity, between musical works. The method should measure similarity by tempo, the frequency of beats in a musical work, and by rhythm, the relationship of one note to the next and the relationship of all notes to the beat. Additionally, a robust method should withstand “beat doubling” effects, where the tempo is misjudged by a factor of two, or confusion by energy peaks that do not occur in tempo or are insufficiently strong.

### SUMMARY

Embodiments of the present invention provide a robust method and system for determining the similarity measure between audio works. In accordance with an embodiment of the present invention a method is provided to quantitatively measure the rhythmic similarity or dissimilarity between two or more auditory works. The method compares the measure of rhythmic self-similarity between multiple auditory works by using a distance measure. The rhythmic similarity may be computed using a measure of average self-similarity against time.

In accordance with an embodiment of the present invention, a beat spectrum is computed for each auditory work which may be compared based upon a distance measure. The distance measure computes the distance between the beat spectrum of one auditory work and the beat spectrum of other audio works in an input set of auditory works. For example, the Euclidean distance between two or more beat spectra results in an appropriate measure of similarity between the musical or audio works. Many possible distance functions which yield a distance measurement correlated to the rhythmic similarity may be used. The result is a measurement of similarity by rhythm and tempo between various audio works.

This method does not depend upon absolute acoustic characteristics of the audio work such as energy or pitch. In particular, the same rhythm played on different instruments will yield the same beat spectrum and similarity measure. For example, a simple tune played on a harpsichord will result in an approximately identical similarity measure when played on a piano, violin, or electric guitar.

Methods of embodiments of the present invention can be used in a wide variety of applications, including retrieving similar works from a collection of works, ranking works by rhythm and tempo similarity, and sequencing musical works by similarity. Such methods work with a wide variety of audio sources.

Applications of embodiments of the present invention include:

1. Automatic music sequencing;

2. Automatic “DJ” for concatenating music with similar tempos;

3. Classification of music into genres;

4. Search for music with similar rhythmic structures but different tempos;

5. Rank music according to similarity measure;

6. “Find me more music like this” feature; and

7. Measuring the comparative rhythmicity of a musical work.

These and other features and advantages of the present invention will be better understood by considering the following detailed description and the associated figures.

### BRIEF DESCRIPTION OF THE FIGURES

Further details of embodiments of the present invention are explained with the help of the attached drawings in which:

FIG. 1 is a flow chart illustrating the steps for a method of analysis in accordance with an embodiment of the present invention;

FIG. 2 shows an example of a beat spectrum B(l) computed for a range of 4 seconds;

FIG. 3 shows the result of the Euclidean distance between beat spectra;

FIG. 4 shows a series of measurements of Euclidian Distance v. Tempo;

FIG. 5 shows the beat spectra of the retrieval data set from Table 1 of FIG. 6; and

FIG. 6 is Table 1 which includes information summarizing data excerpted from a soundtrack.

### DETAILED DESCRIPTION

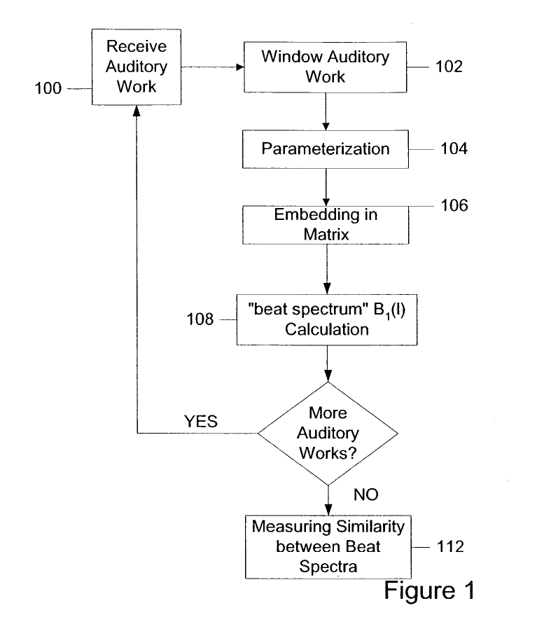

FIG. 1 is a flow chart illustrating the steps for a method of analysis of an auditory work, in accordance with an embodiment of the present invention.

I. Receiving Auditory Work

In step 100 an auditory work, from a group of auditory works to be compared, is received by the system. Examples of audio sources include, but are not limited to, analog signals, such as wav files, and digital signals, such as Musical Instrument Digital Interface (MIDI) files and MPEG3 (MP3) files. In addition, audio signals may be received as input from a compact disc, audio tape, microphone, telephone, synthesizer, or any other medium which transmits audio signals. However, it is understood that embodiments of the present invention may be utilized with any type of auditory work.

II. Windowing Auditory Work

In step 102 the received auditory work is windowed. Such windowing can be done by windowing portions of the audio wave-form. Variable window widths and overlaps can be used. For example, a window may be 256 samples wide, with overlapping by 128 points. For audio sampled at 16 kHz, this results in a 16 mS window width and a 125 per second window rate. However, in alternative embodiments, various other windowing methods, known in the art, can be used.

III. Parameterization

In step 104 the windowed auditory work is parameterized. Each window is parameterized using an analysis function that provides a vector representation of the audio signal portion such as a Fourier transform, or a Mel-Frequency Cepstral Coefficients (MFCC) analysis. Other parameterization methods which can be used include ones based on linear prediction, psychoacoustic considerations or potentially a combination of techniques, such as Perpetual Linear Prediction.

For examples presented subsequently herein, each window is multiplied with a 256-point Hamming window and a Fast Fourier transform (“FFT”) is used for parameterization to estimate the spectral components in the window. However, this is by way of example only. In alternative embodiments, various other windowing and parameterization techniques, known in the art, can be used. The logarithm of the magnitude of the result of the FFT is used as an estimate of the power spectrum of the signal in the window. High frequency components are discarded, typically those above one quarter of the sampling frequency (Fs/4), since the high frequency components are not as useful for similarity calculations for auditory works as lower frequency components. The resulting feature vector characterizes the spectral content of a window.

In alternative embodiments, other compression techniques such as the Moving Picture Experts Group (“MPEG”) Layer 3 audio standard may be used for parameterization. MPEG is a family of standards used for coding audio-visual information in a digital compressed format. MPEG Layer 3 uses a spectral representation similar to an FFT and can be used as a distance measurement which avoids the need to decode the audio. Regardless of the parameterization selected, the desired result obtained is a compact feature vector of parameters for each window.

The type of parameterization selected is not crucial as long as “similar” sources yield similar parameters. However, different parameterizations may prove more or less useful in different applications. For example, experiments have shown that the MFCC representation, which preserves the coarse spectral shape while discarding fine harmonic structure due to pitch, maybe appropriate for certain applications. A single pitch in the MFCC domain is represented by roughly the envelope of the harmonics, not the harmonics themselves. Thus, MFCCs will tend to match similar timbres rather than exact pitches, though single-pitched sounds will match if they are present.

Psychoacoustically motivated parameterizations, like those described by Slaney in “Auditory toolbox,” Technical Report #1998-010, Internal Research Corporation, Palo Alto, Calif., 1998, maybe especially appropriate if they better reproduce the human listeners' judgements of similarity.

Thus, methods in accordance with embodiments of the present invention are flexible and can subsume most any existing audio analysis method for parameterizing. Further, the parameterization step can be tuned for a particular task by choosing different parameterization functions, or for example by adjusting window size to maximize the contrast of a resulting similarity matrix as determined in subsequent steps.

IV. Embedding Parameters in a Matrix

Once the auditory work has been parameterized, in step 106 the parameters are embedded in a 2-dimensional representation. One way of embedding the audio is described by the present inventor J. Foote in “Visualizing Music and Audio Using Self-Similarity,” Proc. ACM Multimedia 99, Orlando, Fla., the full contents of which is incorporated herein by reference. However, in alternative embodiments, various other methods of embedding audio, known in the art, may be used.

In the embedding step a key is a measure of the similarity, or dissimilarity (D) between two feature vectors vᵢ and vⱼ. As discussed above, the feature vectors, vᵢ and vⱼ, are determined in the parameterization step for audio windows i and j.

A. Euclidean Distance

One measure of similarity between the feature vectors is the Euclidean distance in a parameter space, or the square root of the sum of the squares of the differences between the feature vector parameters which is represented as follows:

D_{E}(i,j)≡∥vᵢ−vⱼ∥

B. Dot Product

Another measurement of feature vector similarity is a scalar dot product of feature vectors. In contrast with the Euclidean distance, the dot product of the feature vectors will be large if the feature vectors are both large and similarly oriented. The dot product can be represented as follows:

D_{d}(i,j)≡vᵢ·vⱼ

C. Normalized Dot Product

To remove the dependence on magnitude, and hence energy, in another similarity measurement the dot product can be normalized to give the cosine of the angle between the feature vector parameters. The cosine of the angle between feature vectors has the property that it yields a large similarity score even if the feature vectors are small in magnitude. Because of Parseval's relation, the norm of each feature vector will be proportional to the average signal energy in a window to which the feature vector is assigned. The normalized dot product which gives the cosine of the angle between the feature vectors utilized can be represented as follows:

D_{C}(i,j)≡(vᵢ·vⱼ)/∥vᵢ∥∥vⱼ∥

D. Normalized Dot Product with Stacking

Using the cosine measurement means that similarly-oriented feature vectors with low energy, such as those containing silence, will be spectrally similar, which is generally desirable. The feature vectors will occur at a rate much faster than typical musical events in a musical score, so a more desirable similarity measure can be obtained by computing the feature vector correlation over a larger range of windows “s” (a range of windows is referred to herein as a “stack”). The larger range also captures an indication of the time dependence of the feature vectors. For a window to have a high similarity score, feature vectors of a stack must not only be similar but their sequence must be similar as well. A measurement of the similarity of feature vectors vᵢ and vⱼ over a stack s can be represented as follows:

D(i,j,s)≡1/w ΣD(i+k,j+k)

Considering a one-dimensional example, the scalar sequence (1,2,3,4,5) has a much higher cosine similarity score with itself than with the sequence (5,4,3,2,1).

Note that the dot-product and cosine measures grow with increasing feature vector similarity while Euclidean distance approaches zero. To get a proper sense of similarity between the measurement types, the Euclidean distance can be inverted. Other reasonable distance measurements can be used for distance embedding, such as statistical measures or weighted versions of the metric examples disclosed previously herein.

The above described distance measures are explanatory only. In alternative embodiments, various other measures, known in the art, may be used.

E. Embedded Measurements in Matrix Form

A distance measure D is a function of two frames, or instances in the source signal. It may be desirable to consider the similarity between all possible instants in a signal. This is done by embedding distance measurements D in a two dimensional matrix representation S as depicted in step 106 of FIG. 1. The matrix S contains the similarity calculated for all windows, or for all the time indexes i and j such that the i,j element of the matrix S is D(i,j). In general, S will have maximum values on the diagonal because every window will be maximally similar to itself.

The matrix S can be visualized as a square image such that each pixel i,j is given a gray scale value proportional to the similarity measure D(i,j) and scaled such that the maximum value is given the maximum brightness. These visualizations enable the structure of an audio file to be clearly seen. Regions of high audio similarity, such as silence or long sustained notes, appear as bright squares on the diagonal. Repeated figures, such as themes, phrases, or choruses, will be visible as bright off-diagonal rectangles. If the music has a high degree of repetition, this will be visible as diagonal stripes or checkerboards, offset from the main diagonal by the repetition time.

V. Automatic Beat Analysis and the “Beat Spectrum”

An application for the embedded audio parameters as illustrated in FIG. 1 is for beat analysis as illustrated by step 108 of FIG. 1. For beat analysis, both the periodicity and relative strength of beats in the music can be derived. Measurement of self-similarity as a function of the lag to identify rhythm in music will be termed herein the “beat spectrum” B(l). Highly repetitive music will have strong beat spectrum peaks at the repetition times. This reveals both tempo and the relative strength of particular beats, and therefore can distinguish between different kinds of rhythms at the same tempo. Peaks in the beat spectra correspond to periodicities in the audio. A simple estimate of the beat spectrum can be found by summing S along the diagonal as follows:

B(1)≈ΣS(k,k+1)

B(0) is simply the sum along the main diagonal over some continuous range R, B(l) is the sum along the first sub-diagonal, and so forth.

A more robust definition of the beat spectrum is the auto-correlation of S as follows:

B(k,1)=ΣS(i,j)S(i+k,j+1)

However, because B(k,1) will be symmetrical, it is only necessary to sum over one variable, giving the one dimensional result B(1). The beat spectrum B(1) provides good results across a range of musical genres, tempos and rhythmic structures.

The beat spectrum discards absolute timing information. In accordance with embodiments of the present invention, the beat spectrum is introduced for analyzing rhythmic variation over time. A spectrogram images Fourier analysis of successive windows to illustrate spectral variation over time. Likewise, a beat spectrogram presents the beat spectrum over successive windows to display rhythmic variation over time.

The beat spectrum is an image formed by successive beat spectra. Time is on the x axis, with lag time on the y axis. Each pixel in the beat spectrogram is colored with the scaled value of the beat spectrum at the time and lag, so that beat spectrum peaks are visible as bright bars in the beat spectrogram. The beat spectrogram shows how tempo varies over time. For example, an accelerating rhythm will be visible as bright bars that slope downward, as the lag time between beats decreases with time.

Once the beat spectrum has been calculated, as described with respect to step 108, a determination is made in step 110 as to whether there are additional auditory works for which a comparison is to be made. If it is determined that there are additional auditory works control is returned to step 100 and the method continues for each additional auditory work. If however, it is determined that there are no more additional auditory works to be compared control passes to step 112.

While method steps 100-108 has been described as computing beat spectrum for each auditory work in series, it will be understood that steps 100-108 could be performed in parallel, the beat spectrum for each auditory work being computed at the same time.

VI. Measuring the Similarity Between Beat Spectra by Rhythm and Tempo

Once the beat spectra of two or more auditory works has been computed, the method measures the similarity between two or more beat spectra 112. The beat spectra are functions of lag time l. In practice, l is discrete and finite.

In an embodiment, the beat spectra are truncated to L number of discrete values which form L-dimensional vectors, B₁(L) and B₂(L). For example, the short-lag spectra and long-lag spectra are disregarded. The short and long lag spectra are the portions of the beat spectra where the lag time is small and large, respectively. There will always be a peak representing a high similarity measure where lag time equals zero because this represents the self-comparison of the vector parameters at the same instants during calculation of the beat spectra, and thus, is not informative in determining the similarity measure. Additionally, the short-lag spectra may be too rapid to be considered as rhythm, and thus, not informative.

Long-lag times are less informative because of repetition of rhythm in the audio work. It is more efficient to disregard the data at long-lag times because the same information may be replicated in the data at a shorter-lag time. Additionally, at long-lag times, the beat spectral magnitude will taper because of the width of the window of the correlation, making the data not informative. In one embodiment, the first 116 ms of a short-lag spectra and 4.75 s of a long-lag spectra are disregarded. The result is a zero-mean vector having a length of L values. In one embodiment, the lags may range from approximately 117 ms to approximately 4.74 s for each music excerpt. However, in another embodiment, the lags may range from a few milliseconds to more than five seconds. It will be apparent to one skilled in the art that the range for disregarding the short and long lag time will vary.

In step 112, the rhythmic similarity between the beat spectra is computed after applying a distance function to the L-dimensional vectors. Many possible distance functions which yield a distance measurement directly or inversely correlated to the rhythmic similarity may be used. For example, a distance function which yields a smaller distance value correlated with increasing rhythmic similarity and yields a larger distance value correlated with decreasing rhythmic similarity is appropriate.

A. Euclidean Distance

One measure of similarity between two or more beat spectra vectors is the Euclidean distance in a parameter space, or the square root of the sum of the squares of the differences between the vector parameters. This parameter may be represented as follows:

D_{E}(i,j)≡∥vᵢ−vⱼ∥

B. Dot Product

Another measurement of beat spectra vector similarity is a scalar dot product of two beat spectra vectors. In contrast with the Euclidean distance, the dot product of the vectors will be large if the vectors are both large and similarly oriented. Similarly, the dot product of the vectors will be small if the vectors are both small and similarly oriented. The dot product can be represented as follows:

D_{d}(i,j)≡vᵢ·vⱼ

C. Normalized Dot Product

In another similarity measurement, the dependence on magnitude, and hence beat spectra energy, may be removed. In one embodiment, to accomplish independence from magnitude, the dot product can be normalized to give the cosine of the angle between the two beat spectra vector parameters. The cosine of the angle between vectors has the property that it yields a large similarity measurement even if the vectors are small in magnitude. The normalized dot product, which gives the cosine of the angle between the beat spectra vectors, can be represented as follows:

D_{C}(i,j)≡(vᵢ·vⱼ)/∥vᵢ∥∥vⱼ∥

D. Fourier Beat Spectral Coefficients

In another similarity measurement, a Fourier Transform is computed for each beat spectral vector. This distance measure is based on the Fourier coefficients of the beat spectra. These coefficients represent the spectral shape of the beat spectra with fewer parameters. In one embodiment, a compact representation of the beat spectra simplifies computations for determining the distance measure between beat spectra. Fewer elements speeds distance comparisons and reduces the amount of data that must be stored to represent each file.

In a Fast Fourier Transform (“FFT”), the log of the magnitude is determined and the mean is subtracted from each coefficient. In one embodiment, the coefficients that represent high frequencies in the beat spectra are truncated because high frequencies in the beat spectra are not rhythmically significant. In another embodiment, the zeroth coefficient is also truncated because the DC component is insignificant for zero-mean data. Following truncation, the cosine distance metric then is computed for the remaining zero-mean Fourier coefficients. The result from the cosine distance function is the final distance metric.

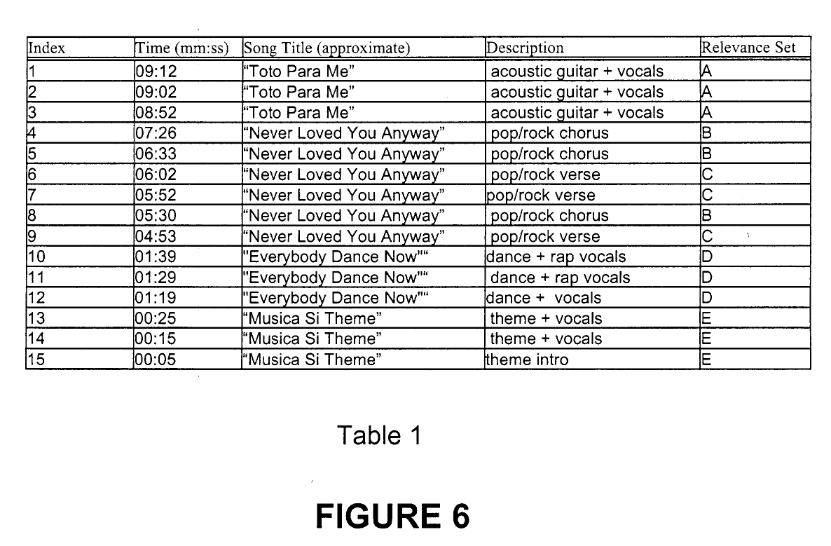

Experimentally, the FFT measure performs identically to the cosine metric using fewer coefficients from the input data of Table 1 of FIG. 6. The number of coefficients was reduced from 120 to 25. The 20.83 percent reduction in the number of coefficients yielded 29 of 30 relevant documents or 96.7% precision. This performance was achieved using an order of magnitude fewer parameters. Though the input data set is small, the methods presented here are equally applicable to any number and size of auditory works. A person skilled in the art may apply well-known database organization techniques to reduce the search time. For example, files can be clustered hierarchically so that search cost increases only logarithmically with the number of files.

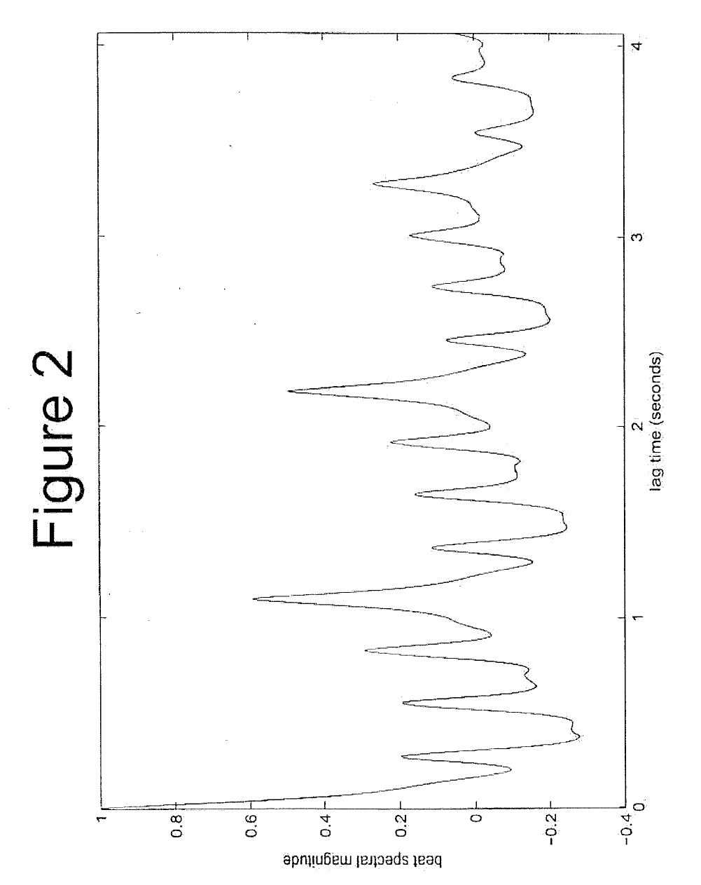

FIG. 2 shows an example of a beat spectra B(1) computed for a range of 4 seconds from Table 1 of FIG. 6 excerpt 15. As discussed above, in order to simplify computation of the distance between beat spectra, short and long lag times may be disregarded.

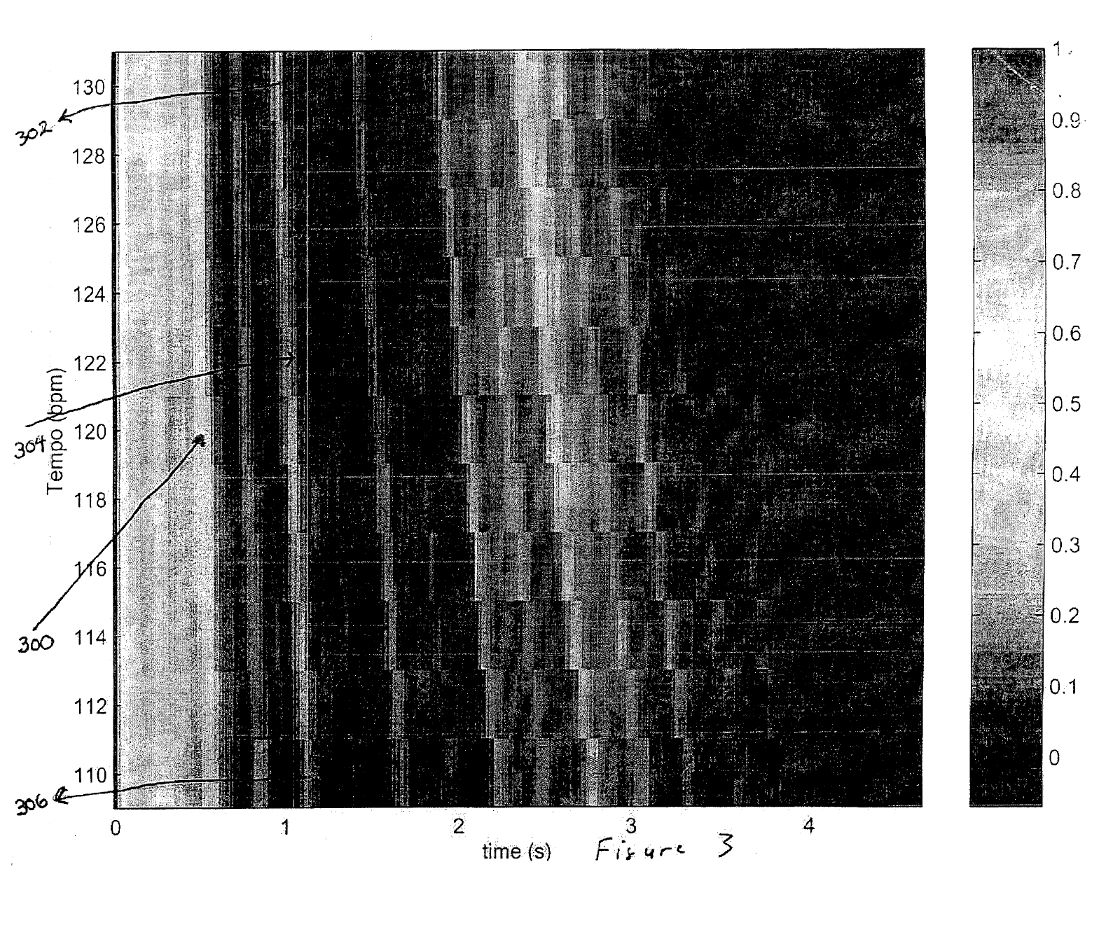

FIG. 3 shows the result of the Euclidean distance between beat spectra of 11 tempo variations at 2 bpm intervals from 110 to 130 bpm. This Figure illustrates that the Euclidean distance between beat spectra may be used to distinguish musical works by tempo. The colored bars represent the pair-wise squared Euclidean distance between a pair of beat spectra. Each excerpt in the set is a different tempo version of an otherwise identical musical excerpt. In order to achieve identical excerpts with differing tempos, the duration of the musical waveform was changed without altering pitch. The original excerpt was played at 120 bpm. Ten tempo variations were generated from the original excerpt. The beat spectra for each excerpt was computed and the pair-wise squared Euclidean distance was computed for each pair of beat spectra. Each vertical bar shows the Euclidean distance between one source file and all other files in the set. The source file is represented where each vertical bar has an Euclidean distance of zero. Location 300 shows a strong beat spectral peak at time 0.5 seconds. This beat spectral peak corresponds to the expected peak from a tempo of 120 beats per minute (“bpm”), or a period of one-half second.

As can be seen in FIG. 3, the Euclidean distance increases relatively monotonically for increasing tempo values. For example, the beat spectral peak 302 at tempo 130 bpm occurs slightly earlier in time than does the beat spectral peak 304 at tempo 122 bpm. In addition, the beat spectral peak 304 at tempo 122 bpm occurs slightly earlier in time than does the beat spectral peak 306 at tempo 110 bpm. The slight offset of the spectral peaks indicates a monotonic increase in Euclidean distance for increasing tempos. Thus, the Euclidean distance can be used to rank music by tempo.

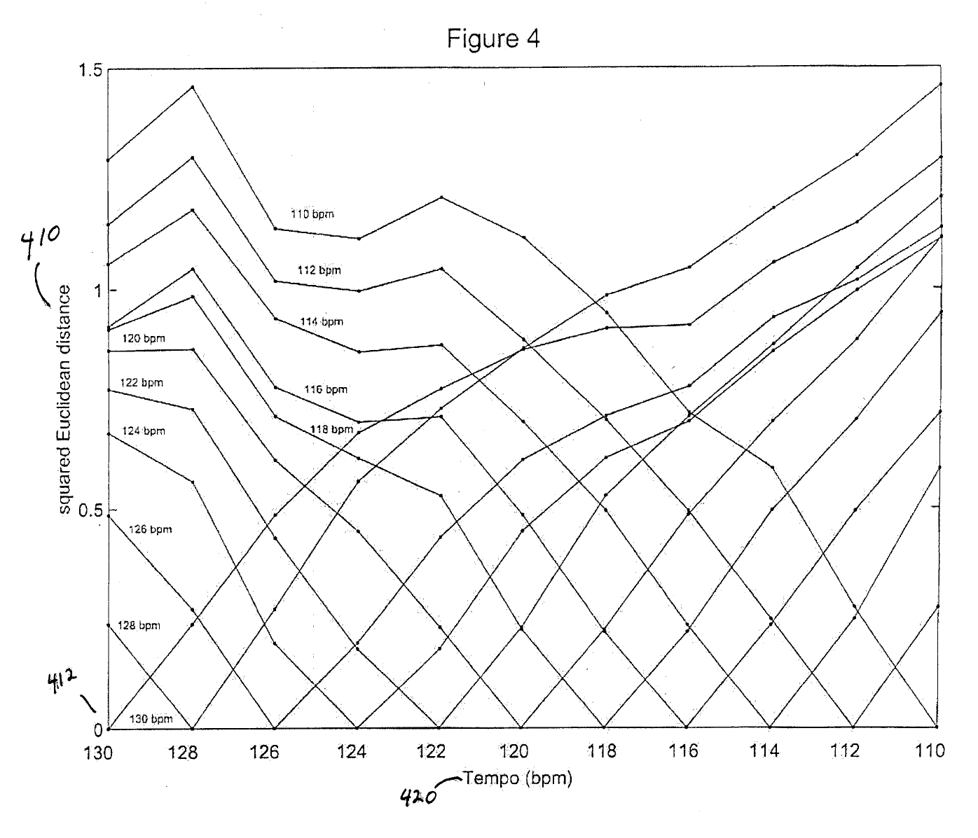

FIG. 4 shows a series of measurements of Euclidian Distance between beat spectra 410 versus Tempo 420. Here, eleven queries are represented with tempos ranging from 110 bpm to 130 bpm. Each line curve represents the Euclidean distance of one excerpt, or query, in comparison with all excerpts in the data set. For example, in a data set with N excerpts, one of the N excerpts is chosen as a query. The query is compared to all N excerpts in the data set using the Euclidean distance function. The Euclidean distance is zero where the self-comparison of the excerpt comprising the query was performed. Accordingly, the source file is represented where the Euclidean distance is zero 412. Additionally, the point in the graph where the Euclidian distance is zero shows the query's tempo in beats per minute.

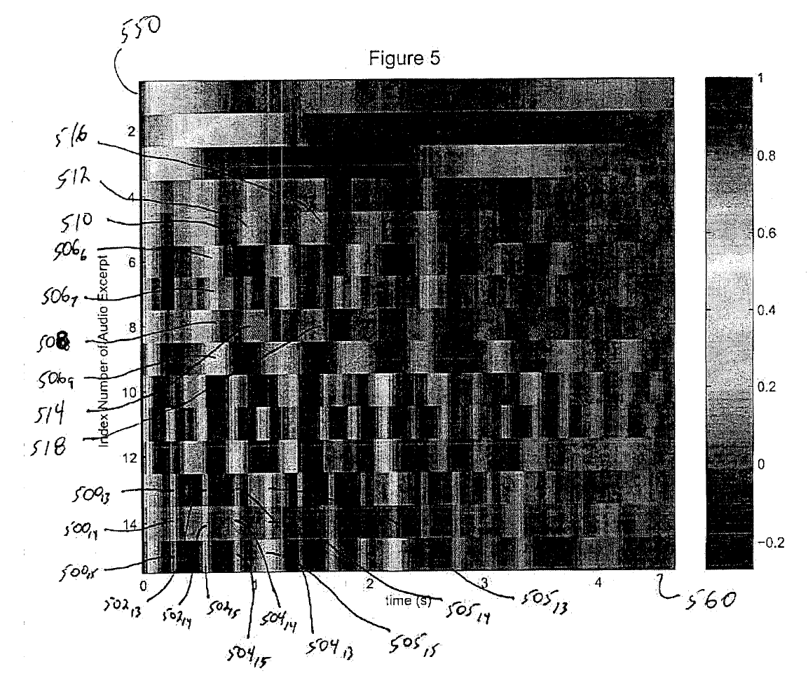

FIG. 5 shows the beat spectra of the retrieval data set from Table 1 of FIG. 6.

Table 1 of FIG. 6 summarizes data excerpted from a soundtrack. Multiple ten-second samples of 4 songs were extracted. Each song is represented by three ten-second excerpts. Although judging relevance for musical purposes is generally a complex and subjective task, in this case each sample is assumed to be relevant to other samples of the same song and irrelevant to samples within other songs. The pop/rock song in this embodiment is an exception to this assumption because the verse and chorus are markedly different in rhythm. Accordingly, the verse and chorus of the pop/rock song are assumed not to be relevant to each other. Thus, the chorus and verse for the pop/rock song, “Never Loved You Anyway,” are each represented by three ten-second excerpts.

In total, Table 1 of FIG. 6 summarizes three ten-second samples from five relevance sets, where the relevance sets are comprised of three songs and two song sections, yielding 15 excerpts. The excerpts comprising each relevance set are similar to each other in rhythm and tempo. The relevance sets represent a high similarity measure of the beat spectra between the excerpts in each set.

In FIG. 5, the index numbers from each 10-second excerpt, shown on the y-axis 550, are plotted versus time in seconds, shown on the x-axis 260. Each row in the graph represents the beat spectra for each distinct excerpt. The song “Musica Si Theme” is represented by excerpt 13, 14 and 15 in Table 1, FIG. 6. The beat spectra of excerpt 13, 14 and 15 are similar. Rows 500₁₃, 500₁₄, 500₁₅ in FIG. 5 show bright bars at the same instance in time, approximately 0.25 seconds, for each beat spectra of excerpts 13, 14, 15 of Table 1 FIG. 6, respectively. Likewise, another set of bright bars are present at the same instance in time, approximately 0.50 seconds, for each beat spectra as shown in locations 502₁₃, 502₁₄, 502₁₅. Further, locations 505₁₃, 505₁₄, 505₁₅ also shows a bright bar at the same instance in time. The repetition of the bright bars, signaling high self-similarity, within the beat spectra of excerpt 13, as illustrated by row 500₁₃, is nearly mirrored by the repetition of the bright bars within the beat spectra of excerpt 15, as illustrated by row 500₁₅. Moreover, the beat spectra of excerpt 14, illustrated by row 500₁₄ resembles the beat spectra of excerpts 13 and 15, as illustrated by rows 500₁₃ and 500₁₅, respectively. Thus, excerpts 13, 14 and 15 comprise the same relevance set.

Referring again to Table 1 of FIG. 6, the song “Never Loved You Anyway” is represented by two relevance sets, relevance sets B and C. In Table 1, excerpts 6, 7 and 9 comprise relevance set C. Locations 506₆, 506₇, 506₉ illustrate repetition of the bright bars at the same instance in time within the beat spectra of excerpts 6, 7 and 9. The bright bar from excerpt 8, depicted by location 508, however, is not aligned with the bright bars from locations 506₆, 506₇, 506₉. Rather, 508 is more closely aligned with excerpt 5, as depicted by location 510. Moreover, locations 512 and 514 from excerpts 5 and 8, respectively, are closely aligned. Additionally, locations 516 and 518 from excerpts 5 and 8, respectively are also closely aligned. Thus, excerpts 5 and 8 are grouped within the same relevance set, relevance set B, as shown in Table 1 of FIG. 6.

VII. Applications

A. Automatic “DJ” for Concatenating Music with Similar Rhythms and/or Tempos

Given a measure of rhythmic similarity, a related problem is to sequence a number of music files in order to maximize the similarity between adjacent files. This allows for smoother segues between music files, and has several applications. If the user has selected a number of files to put on a CD or recording media of limited duration, then the files can be arranged by rhythmic similarity.

An application which uses the rhythmic and tempo similarity measure between various audio sources may arrange songs by similar tempo so that the transition between each successive song is smooth. An appropriately sequenced set of music can be achieved by minimizing the beat-spectral difference between successive songs. This ensures that song transitions are not jarring.

For example following a particularly slow or melancholic song with a rapid or energetic one may be quite jarring. In this application, two beat spectra are computed for each work, one near the beginning of the work and one near the end. The likelihood that a particular transition between works will be appropriate can be determined from the beat spectral distance between the ending segment of the first work and the starting segment of the second.

Given N works, we can construct a distance matrix whose i,jth entry is the beat spectral distance between the end of work i and the start of work j. Note that this distance matrix is not symmetrical because in general the distance between work i and work j is not identical to the distance between work j and work i. Thus the distance matrix will generally not be symmetric. The task is now to order the selected songs such that the sum of the inter-song distances is a minimum. In matrix formulation, we wish to find the permutation of the distance matrix that will minimize the sum of the superdiagonal.

A greedy algorithm may be applied in order to find a near-optimal sequence. A greedy algorithm is an algorithm that performs a single procedure in the algorithm by picking a local optimum until the procedure can no longer be performed. An example of a greedy algorithm is Kruskal's Algorithm which picks an edge with the least weight in a minimum spanning tree. Variations on the methods of the present invention include constraints such as requiring the sequence to start or end with a particular work. The particular application may follow any number of algorithms in order to determine its play list. The process of transitioning between songs such that there is a smooth segue way between songs is done manually by expert DJs and by vendors of “environmental” music, such as Muzak™.

B. Automatic Sequencing by Template

A variation on this last technique is to create a ‘template’ of works with a particular rhythm and sequence. Given a template, an algorithm can automatically sequence a larger collection of music according to similarity to the template, possibly with a random element so that the sequence is unlikely to repeat exactly. For example, a template may specify fast songs in the beginning, moderate songs in the middle, and progressively move towards slower songs within the song collection as time passes.

C. Classification of Music into Genres

In another application, the source audio may be classified into genres of music. The beat spectra of a musical work can be represented by corresponding Fourier coefficients. The Fourier coefficients comprise a vector space. Accordingly, many common classification and machine-learning techniques can be used to classify the musical work based upon the work's corresponding vector representation. For example, a statistical classifier may be constructed to categorize unknown musical works into a given set of classes or genres. Genres of music may include blues, classical, dance, jazz, pop, rock, and rap. Examples of statistical classification methods include linear discriminate functions, Mahalonobis distances, Gaussian mixture models, and non-parametric methods such as K-nearest neighbors. Moreover, various supervised and unsupervised classification methods may be used. For example, unsupervised clustering may automatically determine different genre or other classification characteristics of an auditory work.

D. Search for Music with Similar Rhythmic Structures but Different Tempos

In another application of the present invention, a search for music with similar rhythmic structures but differing tempos may be performed. In conducting such a search, the beat spectra shall be normalized by scaling the lag time. In one embodiment, normalization may be accomplished by scaling the lag axis of all beat spectra such that the largest peaks coincide. In this manner, the distance measure finds rhythmically similar music regardless of the tempo. Acceptable distance measures include Euclidean distance, dot product, normalized dot product, and Fourier transforms. However, any distance measure that yields a distance measurement directly or inversely correlated to the rhythmic similarity can be used on the scaled spectra.

E. Rank Music According to Similarity Measure

In another application, music in a user's collection is analyzed using the “beat spectrum,” metric. This metric provides a method of automatically characterizing the rhythm and tempo of musical recordings. The beat spectrum is calculated for every music file in the user's collection. Given a similarity measure, files can be ranked by similarity to one or more selected query files, or by similarity with any other musical source from which a beat spectrum can be measured. This allows users to search their music collections by rhythmic similarity.

F. “Find Me More Music Like This” Feature

In an alternative embodiment, a music vendor on the internet or other location may implement a “find me more music like this” service. A user selects a musical work and submits the selected musical work as a query file in a “find me more music like this” operation. The system computes the beat spectra of the query file and computes the similarity measure between the query file and various songs within the music vendor's collection. The system returns music to the user according to the similarity measure. In one embodiment, the returned music's similarity measure falls within a range of acceptability. For example, in order to return the top 10% of music within the collection which is closest to the rhythm and tempo of the query file, the system shall rank each musical work's similarity measure. After ranking is completed, the system shall return the top 10% of music with the highest similarity measure.

G. Measuring the Comparative Rhythmicity of a Musical Work

Another application of the beat spectrum is to measure the “rhythmicity” of a musical work, or how much rhythm the music contains. For example, the same popular song could be recorded in two versions, the first with only voice and acoustic guitar, and the second with a full rhythm section including bass and drums. Even though the tempo and melody would be the same, most listeners would report that the first “acoustic” version had less rhythmicity, and might be more difficult to keep time to than the second version with drums. A measure of this difference can be extracted from the beat spectrum, by looking at the excursions in the mid-lag region. A highly rhythmic work will have large excursions and periodicity, while less rhythmic works will have correspondingly smaller peak-to-peak measurements. So a simple measure of rhythmicity is the maximum normalized peak-to-trough excursion of the beat spectrum. A more robust measurement is to look at the energy in the middle frequency bands of the Fourier transform of the beat spectrum. The middle frequency bands would typically span from 0.2 Hz (one beat every five seconds) to 5 Hz (five beats per second). Summing the log magnitude of the appropriate Fourier beat spectral coefficients results in a quantitative measure of this.

It should be understood that the particular embodiments described herein are only illustrative of the principles of the present invention, and various modifications could be made by those skilled in the art without departing from the scope and spirit of the invention.

What is claimed is:

1. A method for comparing at least two auditory works, comprising the steps of:
receiving a first auditory work and a second auditory work;
determining a first feature vector representative of said first auditory work;
determining a second feature vector representative of said second auditory work;
calculating a first beat spectrum from said first feature vector;
calculating a second beat spectrum from said second feature vector; and,
measuring a similarity value of said first beat spectrum and said second beat spectrum.

2. The method of claim 1, further comprising the steps of:
windowing said first auditory work into a first plurality of windows;
windowing said second auditory work into a second plurality of windows;
wherein said step of determining said first feature vector includes the step of:
determining a first plurality of feature vectors representative of said first plurality of windows; and
wherein said step of determining said second feature vector includes the step of:
determining a second plurality of feature vectors representative of said second plurality of windows.

3. The method of claim 2, wherein said step of calculating a first beat spectrum includes the steps of:
determining a first similarity between feature vectors of said first plurality of feature vectors; and,
calculating said first beat spectrum from said first similarity; and
wherein the step of calculating a second beat spectrum includes the steps of:
determining a second similarity between feature vectors of said second plurality of feature vectors; and,
calculating said second beat spectrum from said second similarity.

4. The method of claim 1, wherein said first beat spectrum is a function of a lag time, and
wherein said second beat spectrum is a function of said lag time.

5. The method of claim 4, wherein said first beat spectrum is truncated based upon said lag time and said second beat spectrum is truncated based upon said lag time.

6. The method of claim 1, wherein said step of measuring includes measuring a Euclidean distance between said first beat spectrum and said second beat spectrum.

7. The method of claim 1, wherein said step of measuring includes measuring a dot product between said first beat spectrum and said second beat spectrum.

8. The method of claim 1, wherein said step of measuring includes measuring a normalized dot product between said first beat spectrum and said second beat spectrum.

9. The method of claim 1, wherein said step of measuring includes the steps of:
computing a Fourier Transform for said first beat spectrum and said second beat spectrum; and
measuring a Euclidean distance between said Fourier Transform of said first beat spectrum and said second beat spectrum.

10. The method of claim 1, wherein said step of measuring includes the steps of:
computing a Fourier Transform for said first beat spectrum and said second beat spectrum; and
measuring a dot product between said Fourier Transformed first beat spectrum and said second beat spectrum.

11. The method of claim 1, wherein said step of measuring includes the steps of:
computing a Fourier Transform for said first beat spectrum and said second beat spectrum; and
measuring a normalized dot product for said Fourier Transformed first beat spectrum and said second beat spectrum.

12. The method of claim 1, wherein said step of measuring the similarity includes measuring the similarity by rhythm and tempo.

13. The method of claim 1, wherein said step of measuring the similarity includes measuring the similarity by rhythm.

14. The method of claim 1, wherein said step of measuring the similarity includes measuring the similarity by tempo.

15. A method for determining a beat spectrum for an auditory work, comprising the steps of:
receiving an auditory work;
windowing said auditory work into a plurality of windows;
determining a feature vector representative of each of said windows;
computing a similarity matrix for a combination of each said feature vector; and
generating a beat spectrum from said similarity measure.

16. The method of claim 15, wherein said step of computing a similarity matrix is computed based upon a Euclidean distance between said combination of feature vectors.

17. The method of claim 15, wherein said step of computing a similarity matrix is computed based upon a dot product of said combination of feature vectors.

18. The method of claim 15, wherein said step of computing a similarity matrix is computed based upon a dot product of said combination of feature vectors.

19. The method of claim 15, wherein said beat spectrum is a measurement of said similarity matrix as a function of a lag of said auditory work.

20. The method of claim 15 wherein said beat spectrum is utilized for determining a rhythmic variation of said auditory work over time.

21. The method of claim 15, wherein said beat spectrum indicates how a tempo of said auditory work varies over time.
